(19) United States
(12) Patent Application Publication
(10) Pub. No.: US 2026/0323956 A1
(43) Pub. Date: Oct. 15, 2026

(54) PHASE CHANGE MEMORY CELL INCLUDING RESISTIVE ELEMENTS CONNECTED IN PARALLEL

(71) Applicant: STMicroelectronics International N.V., Geneva (CH)

(72) Inventors: Remy BERTHELON, Crolles (FR); Simon DESMOULINS, Corenc (FR); Yannick LE FRIEC, Goncelin (FR)

(73) Assignee: STMicroelectronics International N.V., Geneva (CH)

(21) Appl. No.: 19/637,969

(22) Filed: Apr. 2, 2026

(30) Foreign Application Priority Data
Apr. 14, 2025 (FR) FR2503944

(51) Int. Cl. H10B 63/10; H10B 63/00; H10D 1/00; H10D 1/47; H10N 70/00; H10N 70/20

(52) U.S. Cl. CPC H10B 63/10; H10B 63/82; H10B 63/84; H10D 1/021; H10D 1/474; H10N 70/021; H10N 70/235; H10N 70/826

(57) ABSTRACT

A device includes a phase change memory cell, including at least one first and one second resistive elements, electrically connected in parallel between conductive contacts. The first resistive element has an electric resistance having a first value at a first temperature lower than the crystallization temperature, and a second value at a second temperature higher than the melting temperature, less than or equal to its first value. The second resistive element has an electric resistance having a first value at the first temperature, greater than the first value of the first resistive element, and a second value at the second temperature, less than the second value of the first resistive element.

### BACKGROUND

### Technical Field

The present description generally relates to integrated circuits including Phase Change Memory (PCM) cells.

### Description of the Related Art

A phase change memory cell is a type of non-volatile memory that can be considered as a variable resistance electric dipole where binary information is stored. Conventionally, such a memory cell includes an active portion formed of a phase change material and disposed between two electrodes.

When the material of the active portion is in the crystalline phase, its resistivity is low and makes it possible to code the SET state (usually, logical state 1), whereas in the amorphous phase, its resistivity is higher and makes it possible to code the RESET state (logical state 0).

Temperatures for phase changes are achieved by heating a resistive element of the memory cell by Joule effect. This resistive element corresponds to a heating resistor (heater) which is in thermal and electrical contact with the active portion of the memory cell.

However, it would be beneficial to improve performance of such a memory cell, and in particular in the scope of a matrix of identical memory cells.

### BRIEF SUMMARY

According to one aspect of the present disclosure, a phase change memory cell including an active portion of a phase change material having a crystallization temperature and a melting temperature is provided. The memory cell includes:
a first conductive contact;
at least one first and one second resistive elements, electrically connected in parallel, and electrically coupled to the first conductive contact,
   the first resistive element having an electric resistance having: a first value at a first temperature lower than the crystallization temperature, and a second value at a second temperature higher than the melting temperature, less than or equal to its first value,
   the second resistive element having an electric resistance having: a first value at the first temperature, greater than the first value of the first resistive element, and a second value at the second temperature, less than the second value of the first resistive element;
the active portion, coupled to the first and second resistive elements;
a second conductive contact, coupled to the active portion.

According to one embodiment, the first and second resistive elements each include a first part extending from the first conductive contact to the active portion, the first part of the first resistive element being spaced from the first part of the second resistive element by a first spacer made of an electrically insulating material.

According to one embodiment, the first and second resistive elements each include a second part extending from the first part and located in contact with the first conductive contact, the first spacer covering the second part of the first resistive element.

According to one embodiment, the memory cell includes a second spacer extending along a surface of the first part of the second resistive element, opposite to the first spacer, and covering the second part of the second resistive element.

According to one embodiment, the first and second resistive elements have identical or different thicknesses.

According to one embodiment, at the first temperature, the first value of the electric resistance of the second resistive element is at least 2 times greater than the first value of the electric resistance of the first resistive element.

According to one embodiment, the first resistive element and/or the second resistive element are made of materials based on titanium silicon and/or tungsten nitride.

According to one embodiment, the active portion is made of a chalcogenide, preferably a ternary chalcogenide compound.

According to another aspect, there is provided an integrated circuit including a matrix of identical memory cells according to any of the preceding characteristics.

According to another aspect, there is provided a method for manufacturing at least one memory cell according to any one of the preceding characteristics, including the following steps:
making a first insulating layer and at least one first conductive contact passing therethrough to open out onto an upper face;
making a second insulating layer covering the first insulating layer and the first conductive contact;
making at least one opening through the second insulating layer and opening out onto the first conductive contact;
depositing a first thin conductive layer onto a flank of the opening, and local etching to obtain the first resistive element;
depositing a thin insulating layer onto a flank of the first resistive element, and local etching to obtain a first spacer;
depositing a second thin conductive layer onto a flank of the first spacer, and local etching to obtain the second resistive element;
making the active portion;
making the second conductive contact.

According to one embodiment, the first thin conductive layer is deposited by chemical vapor deposition.

According to one embodiment, the second thin conductive layer is deposited by atomic layer deposition.

According to one embodiment, the first thin conductive layer and/or the second thin conductive layer are made of a material based on a titanium silicon and/or tungsten nitride.

According to one embodiment, the manufacturing method includes, before the step of making the active portion, a step of filling the opening, followed by a step of making a continuous layer of the phase change material.

According to another aspect, there is provided a method for manufacturing an integrated circuit including a matrix of identical memory cells simultaneously made by the method according to any one of the preceding characteristics.

In one embodiment, a method includes depositing a first insulating layer on a first conductive contact of a memory cell, exposing the first conductive contact by forming a trench in the insulating layer, depositing a first resistive element of the memory cell in the trench on a top surface of the first conductive contact, and depositing a second resistive element of the memory cell in the trench on the top surface of the first conductive contact adjacent to the first resistive element. The method includes filling the trench with a first insulating material, depositing a layer of phase change material of the memory cell on a top surface of the resistive element, on a top surface of the second resistive element, and on a top surface of the first insulating material, and depositing a second conductive contact on the layer of phase change material.

### BRIEF DESCRIPTION OF THE SEVERAL VIEWS OF THE DRAWINGS

Further advantages and characteristics of the disclosure will become apparent upon examining the detailed description of non-limiting embodiments and implementations, and from the appended drawings wherein:

FIG. 1A is a schematic and partial transverse cross-section view of an integrated circuit including memory cells according to one embodiment;

FIG. 1B illustrates an example of variations as a function of the temperature of the equivalent electric resistance associated with two resistive elements of a memory cell according to one embodiment; and

FIG. 2A, FIG. 2B, FIG. 2C, FIG. 2D, FIG. 2E, and FIG. 2F illustrate different steps of a method for manufacturing an integrated circuit including memory cells according to one embodiment.

### DETAILED DESCRIPTION

In the figures and in the following description, the same references represent identical or similar elements. In addition, the different elements are not represented to scale in such a way as to favor clarity of the figures. Furthermore, the different embodiments and alternatives are not exclusive of each other and may be combined together.

Unless otherwise indicated, the terms “substantially,” “about,” “in the order of” mean to the nearest 10%, and preferably to the nearest 5%. Furthermore, the terms “between . . . and . . .” and equivalents mean that bounds are included, unless otherwise stated.

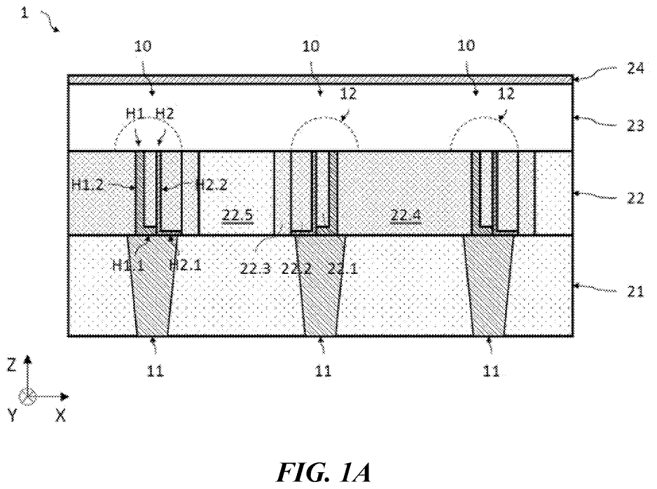

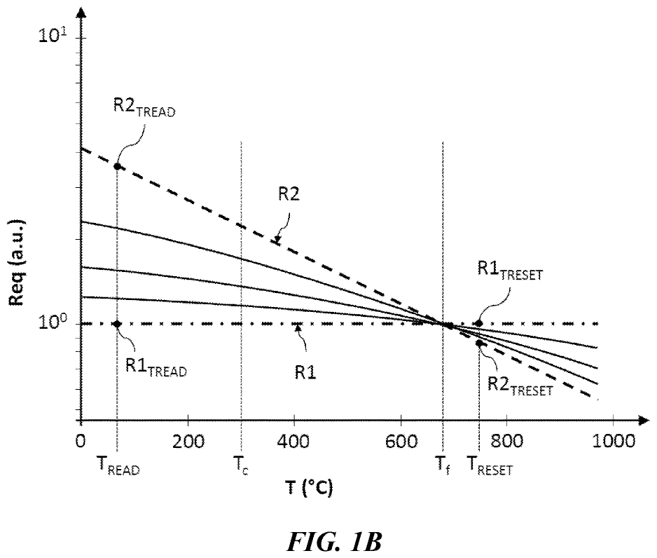

FIG. 1A is a schematic and partial transverse cross-section view of an integrated circuit 1 including at least one phase change memory cell 10 according to one embodiment, and herein a matrix of identical memory cells.

Herein and for the remainder of the description, a three-dimensional direct reference frame XYZ is defined, in which the plane XY is parallel to the main plane of the integrated circuit, and where the axis Z is oriented along the thickness thereof. Furthermore, the terms “lower” and “upper” are understood to be relative to an increasing positioning along the direction +Z.

In general, each memory cell 10 includes at least one lower conductive contact 11, at least two resistive elements H1, H2 electrically connected in parallel, an active portion 12 of a phase change material, and an upper conductive contact 24.

Thus, the resistive elements H1, H2 are electrically coupled, on the one hand, to the lower conductive contact 11, and on the other hand, to the upper conductive contact 24. Each resistive element can thus include a longitudinal part extending from a lower end electrically coupled to the lower conductive contact 11 to an upper end electrically coupled to the upper conductive contact 24. The longitudinal parts of the resistive elements H1, H2 are thereby electrically insulated from each other.

It is recalled that in use, three operations can be performed: a read operation (READ) where the electric resistance of the memory cell 10 is to be determined to know the SET or RESET state thereof; a write programming step (SET state); and an erase programming step (RESET state).

The read operation (READ) consists in determining the electric resistance of the memory cell, for example by applying an electric voltage and measuring the electric current that passes through the memory cell. If the electric current is maximum, this corresponds to an active portion whose material is of a crystalline phase and then has a low electric resistance: the state of the memory cell usually corresponds to the SET state (logical state 1). If, on the other hand, the electric current is minimum, the material of the active portion is then of an amorphous phase and therefore has a high electric resistance: the memory cell has the RESET state (logical state 0). This read operation is performed at a temperature T_{READ} of the memory cell that is lower than the crystallization temperature T_{c} of the phase change material, and may be at ambient temperature (i.e., when using the product, generally between −40 °C and +165 °C).

The write programming operation (SET) corresponds to the crystallization of the material of the active portion. Here, the memory cell can be subjected to an electrical pulse the properties of which (intensity, duration, fall time, etc.) are chosen to bring the temperature of the active portion to a value T_{SET} at least equal to the crystallization temperature T_{c}. The material of the active portion then changes from the amorphous phase to the crystalline phase, and the memory cell then has the SET state.

The erase programming operation RESET corresponds to the amorphization of the material of the active portion. Here, the memory cell can be subjected to an electrical pulse the properties of which (intensity, duration, fall time, etc.) are chosen to bring the temperature of the active portion to a T_{RESET} value greater than the melting temperature T_{f}: T_{RESET}>T_{f}. The material of the active portion changes from the crystalline phase to the amorphous phase, and the memory cell then has the RESET state.

Let's turn back to FIG. 1A. In this example, the integrated circuit 1 includes a lower insulating layer 21, made of an electrically insulating material such as silicon oxide. This layer 21 may rest on a passivation layer (not represented), made of an electrically insulating material such as a silicon nitride.

It is noted that the integrated circuit 1 usually includes a FEOL (Front End Of Line) structure on which the lower insulating layer 21 rests and to which the memory cells 10 are electrically coupled. This FEOL structure includes electronic elements such as the field effect transistors, especially for controlling the memory cells. It is not represented for the sake of clarity. A BEOL (Back End Of Line) structure may also be present under or in the lower insulating layer 21.

Lower conductive contacts 11, made of at least one electrically conductive material, preferably metallic such as copper, tungsten, among others, vertically cross the lower insulating layer 21. In this embodiment, each memory cell 10 includes a conductive contact 11. These conductive contacts 11 have a through-silicon via shape.

An intermediate insulating layer 22, made of at least one electrically insulating material such as a silicon oxide and/or nitride, covers the lower insulating layer 21, and surrounds the resistive elements H1, H2 in the plane XY. It is formed of different insulating portions (spacers, etc.) described later.

Each memory cell 10 includes at least two resistive elements H1, H2, electrically connected in parallel, and electrically coupled to the same lower conductive contact 11 and to the same active portion 12. In this embodiment, it includes two resistive elements, but it could include more resistive elements.

Each resistive element H1, H2 forms a heating element (heater) configured to enable programming of a logical state by phase change of the material of the active portion 12. It is therefore made of an electrically conductive material, and has an electric resistance R the value of which depends on the temperature of the memory cell 10 in use.

The electric resistance R of a resistive element is expressed, in general, as a function of the resistivity ρ of its material, and its dimensions L, l, e, by the following relationship: R=ρ×L/(e×l), where L is its height, l its width and e its thickness.

According to one embodiment, each resistive element H1, H2 has a so-called “wall” architecture, and includes at least one vertical part H1.2, H2.2 having height L along the axis Z, having thickness e here along the axis X, and having width l here along the axis Y. The height L and the width l of each resistive element H1, H2 may be identical. The thicknesses e1 and e2 may be identical or different, as explained later.

Each resistive element H1, H2 may also include a lower part H1.1, H2.1, extending from a lower end of the vertical part H1.2, H2.2 in the plane XY in contact with the lower conductive contact 11. The vertical portion H1.1, H2.1 and the lower portion H1.2, H2.2 are arranged herein in an L-shape. Other arrangements are contemplatable.

The electric resistance R1 of the first resistive element H1 especially has: a first value R1_{TREAD} at a first temperature lower than the crystallization temperature T_{c}, such as the read temperature T_{READ} ; and a second value R1_{TRESET} at a second temperature higher than the melting temperature T_{f}, such as the temperature T_{RESET} for programming the RESET state.

Similarly, the electric resistance R2 of the second resistive element H2 especially has: a first R2_{TREAD} value at the first temperature (read temperature T_{READ}); and a second value R2_{TRESET} at the second temperature (temperature T_{RESET} for programming the RESET state).

The resistive elements H1 and H2 have materials in terms of resistivity and dimensions such that:
at the first temperature (read temperature T_{READ)}, the value R1_{TREAD} is less than the value R2_{TREAD}: R1_{TREAD}<R2_{TREAD}, so that the electric current passes predominantly through the first resistive element H1;
at the second temperature (RESET programming T_{RESET} temperature), the R2_{TRESET} value is lower than the R1_{TRESET} value: R2_{TRESET}<R1_{TRESET}, so that the electric current passes predominantly through the second resistive element H2.

For example, in the case of a phase change material of the germanium antimony tellurium type (GeSbTe, called GST), the crystallization temperature T_{c} may be in the order of 300 °C, and the melting temperature T_{f} may be in the order of 650 °C. These values especially depend on the germanium and antimony content. The T_{READ} temperature may be 25 °C, 50 °C or more lower than T_{c}. This may be the temperature of use of the product, which may be, for example, between about −40 °C and +165 °C. The temperature T_{RESET} may be greater than T_{f} by 25 °C, 50 °C or more, and may be equal to 700 °C, 750 °C or even 800 °C in the case of a temperature T_{f} of about 650 °C.

The first resistive element H1 may have a temperature variation of its resistivity ρ1 which may be constant between the temperatures T_{READ} (for example 25 °C) and T_{RESET} (for example 750 °C.), or may be slightly decreasing, for example by at most 30%, or even 20%, or even 10%.

By way of example, the value ρ1_{TREAD} of the resistivity ρ1 may be between 0.5 and 1 mΩ.cm, and the value ρ1_{TRESET} may be substantially equal to or slightly lower. Thus, the value ρ1_{TREAD} may be equal to about 1 mΩ.cm, and the value ρ1_{TRESET} may be between 0.8 mΩ.cm and 1 mΩ.cm, or even between 0.9 mΩ.cm and 1 mΩ.cm.

The second resistive element H2 may have a temperature variation of its resistivity ρ2 which is more decreasing between the temperatures T_{READ} and T_{RESET}, for example of a half-decade or even of a decade. Furthermore, as indicated previously, the value R2_{TREAD} is greater than R1_{TREAD}, for example 2, 5, or even 10 times greater, while the value R2_{TRESET} is less than R1_{TRESET}.

By way of example, the value ρ2_{TREAD} of the resistivity ρ2 may be between 5 and 10 mΩ.cm, and the value ρ2_{TRESET} may be between 0.5 and 1 mΩ.cm. Thus, the value ρ2_{TREAD} may be equal to about 5 mΩ.cm (above a value ρ1_{TREAD} of 1 mΩ.cm), and the value ρ2_{TRESET} may be equal to 0.8 mΩ.cm (below a value ρ2_{TREAD} of 1 mΩ.cm).

The resistive element H1 and/or the resistive element H2 may be made based on a titanium silicon nitride TiSiN, tungsten, among others. The difference in electrical behavior as a function of temperature can result from the chemical composition of the material, its structural properties (e.g., porosity rate), among others.

Thus, the resistive element H1 may be a TiSiN made by Chemical Vapor Deposition (CVD). By way of example, the CVD deposition may be carried out between about 390 °C and 420 °C, at a pressure of about 5 Torr, and with a precursor tetrakis(dimethylamido)titanium (TDMAT). The change in resistivity as a function of temperature can be adjusted by modulating densification of the material, in particular via the power used during CVD deposition.

Furthermore, the resistive element H2 may be TiSiN produced by Atomic Layer Deposition (ALD). By way of example, the ALD deposition may be carried out between about 400 °C and 450 °C, at a pressure of about 30 Torr. The change in resistivity as a function of temperature can be adjusted by modulating a flowrate of silane SiH4 used after each deposition cycle.

FIG. 1B illustrates an example of changes in temperature of the equivalent electric resistance Req associated with the two resistive elements H1, H2 connected in parallel, of a memory cell 10 similar to that of FIG. 1A.

In this example, it is considered that the active portion is made of a GST material whose crystallization temperature T_{c} is equal to about 300 °C and melting temperature T_{f} is equal to about 650 °C. The temperature T_{READ} is here the ambient temperature of 25 °C, and the temperature T_{RESET} is equal to approximately 750 °C.

In addition, the courses of temperature of the electric resistance Req are compared in the case where the proportion of thickness in both resistive elements is varied. Stated differently, a total thickness emax=e1+e2 is considered and the proportion of each thickness in the total thickness is varied in the following cases: (e1; e2)=(100%; 0%); (75%; 25%); (50%; 50%); (25%; 75%); and (0%; 100%).

In the case (e1; e2)=(100%; 0%), the electric resistance Req corresponds to R1 of the resistive element H1, which varies between a value R1_{TREAD} and a value R1_{TRESET} substantially equal to R1_{TREAD}. The resistive element H1 has a thickness e1 equal to emax.

In the opposite case (e1; e2)=(0%; 100%), the electric resistance Req corresponds to the resistance R2 of the resistive element H2, which varies between a value R2_{TREAD} and a value R2_{TRESET} much lower than R2_{TREAD}. The resistive element H2 has a thickness e2 equal to emax.

At a temperature lower than T_{c} such as the temperature T_{READ}, the electric resistance R1_{TREAD} is lower than R2_{TREAD}, whereas at a temperature higher than T_{f} such as the temperature T_{RESET}, it is the electric resistance R2_{TRESET} that is lower than R1_{TRESET}.

In the cases where (e1; e2)=(75%; 25%), (50%; 50%), and (25%; 75%), the electric resistance Req varies in temperature between the two curves R1 and R2. The choice of the thickness distribution between e1 and e2 makes it possible to especially modulate the distribution of the electric current that passes through each resistive element H1, H2 during a read, write programming and erase programming operation.

Anyway, during the read operation, i.e., at the temperature T_{READ}, the electric current passes predominantly through the resistive element H1 (i.e., more than 50% of the electric current passes through H1), whereas during the erase programming operation, i.e., at the temperature T_{RESET}, the electric current passes predominantly through the resistive element H2 (i.e., more than 50% of the electric current passes through H2).

Let's turn back to FIG. 1A. Each resistive element H1, H2 extends through the intermediate insulating layer 22 over a height L. The vertical part H1.2, H2.2 may extend in parallel to the vertical axis Z, as illustrated herein, or may extend in a tilted way, as illustrated in document EP 3,890,024 A1.

According to one embodiment, the lower parts H1.1, H2.1 of the resistive elements H1, H2 of a same memory cell 10 may be in contact with each other. They are in electrical contact with the same conductive contact 11. On the other hand, the vertical parts H1.2, H2.2 are not in contact with each other, and are spaced apart from each other by a first spacer 22.1. The first spacers 22.1 are portions of the intermediate insulating layer 22 that extend vertically along the axis Z and are located between the vertical parts H1.2, H2.2 of the resistive elements H1, H2 of a same memory cell 10. They cover the lower parts H1.1 of the resistive elements H1. They may be made of silicon nitride.

In this embodiment, the intermediate insulating layer 22 includes other portions that form second spacers 22.2. They extend vertically along the axis Z and are located against the vertical parts H2.2 of the resistive elements H2, opposite to the first spacers 22.1. They cover the lower parts H2.1 of the resistive elements H2. They may be made of silicon nitride.

The intermediate insulating layer 22 may include third spacers 22.3, which extend vertically along the axis Z and are located against a flank of the second spacers 22.2 opposite to the resistive elements H2. They may be made of silicon nitride.

It includes an interlayer portion 22.4 located between each resistive element H1, which can be made, for example, of a silicon nitride. It may also include an interlayer portion 22.5 located between each resistive element H2, and here between the third spacers 22.3 which face each other in the plane XY. It may be made, for example, of a silicon oxide.

Each memory cell 10 includes an active portion 12, made of a phase change material. The active portion 12 is electrically and thermally coupled to the two resistive elements H1, H2. The phase change material may be a chalcogenide, for example a ternary chalcogenide compound, such as a germanium-antimony-tellurium (GST), among others. As mentioned previously, the germanium and antimony content is chosen to obtain the desired values of the crystallization T_{c} and melting T_{f} temperatures, which may be equal to about 300 °C and about 650 °C respectively.

In this embodiment, the active portions 12 are dome-shaped zones of a same continuous layer 23 of the phase change material, which extend on and in contact with the intermediate insulating layer 22 and the resistive elements H1, H2.

Finally, each memory cell 10 includes an upper conductive contact, made of an electrically conductive material. These contacts can herein be zones of a same conductive layer 24 that continuously covers the phase change continuous layer 23. The conductive layer 24 may be made of one or more metal materials such as tungsten, TiN, among others.

It is noted that the memory cells 10 are generally arranged as a matrix of rows and columns, so that each memory cell is at the intersection of a row (bitline) and a column (wordline). They can be controlled by MOS or bipolar selection transistors.

Of course, other memory cell architectures are possible, both with regard to the conductive contacts, the shape of the resistive elements, and that of the active portions.

The memory cell 10, and here the memory cell matrix of the integrated circuit 1, thus have improved performance, both during the read operation and during the RESET programming operation.

Indeed, the fact that the memory cell 10 includes two resistive elements H1, H2 (or even more) connected in parallel, the resistances of which are such that electric current passes predominantly through the resistive element H1 during the read operation (lowest electric resistance R1_{TREAD)}, but through the resistive element H2 during the programming operation RESET (lowest electric resistance R2_{TRESET)}, makes it possible to take advantage of the different properties of these resistive elements H1 and H2 during these operations.

Thus, the inventors have found that the materials likely to be used as a resistive element of a memory cell can have a certain disparity of their electrical behaviors as a function of temperature, for example in terms of resistivity, but also robustness.

Robustness here means the reproducibility of electrical properties in space. Thus, it is expected that the same resistive elements of different identical memory cells of an integrated circuit produce a same heating when they are subjected to an electrical signal of the same intensity.

Also, the resistive element H1 has more interesting electrical properties than those of the resistive element H2 at the temperature T_{READ}: in particular, it has lower resistivity (and therefore lower electric resistance). Also, the fact that the electric current passes predominantly through the resistive element H1 during the read operation especially makes it possible to limit degradation of the performance of the memory cell when it has the SET state. Indeed, when reading the SET state, it is desired to measure a high-intensity electric current insofar as the electric resistance of the active portion is low. It is therefore not desired that the electric current be reduced by a high electric resistance of the resistive element.

On the other hand, the resistive element H2 has more interesting electrical properties than those of the resistive element H1 at the temperature T_{RESET}, for example in terms of robustness. Also, the fact that the electric current passes predominantly through the resistive element H2 during the RESET programming operation makes it possible to improve performance of the memory cell, but also that of the integrated circuit which includes a matrix of identical memory cells.

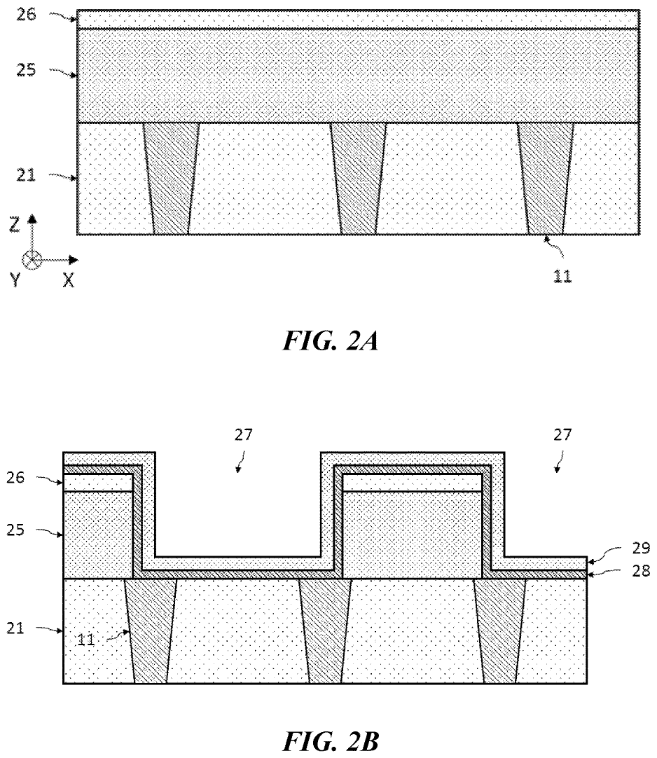

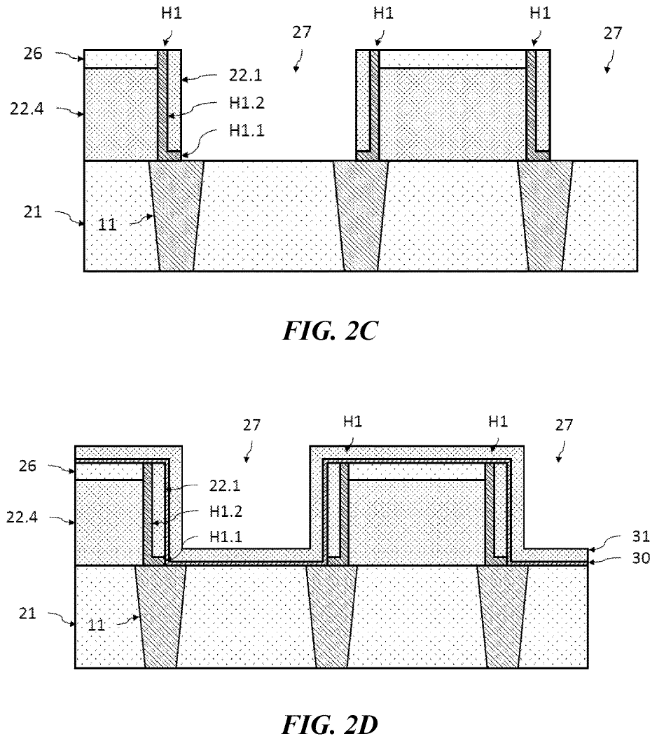

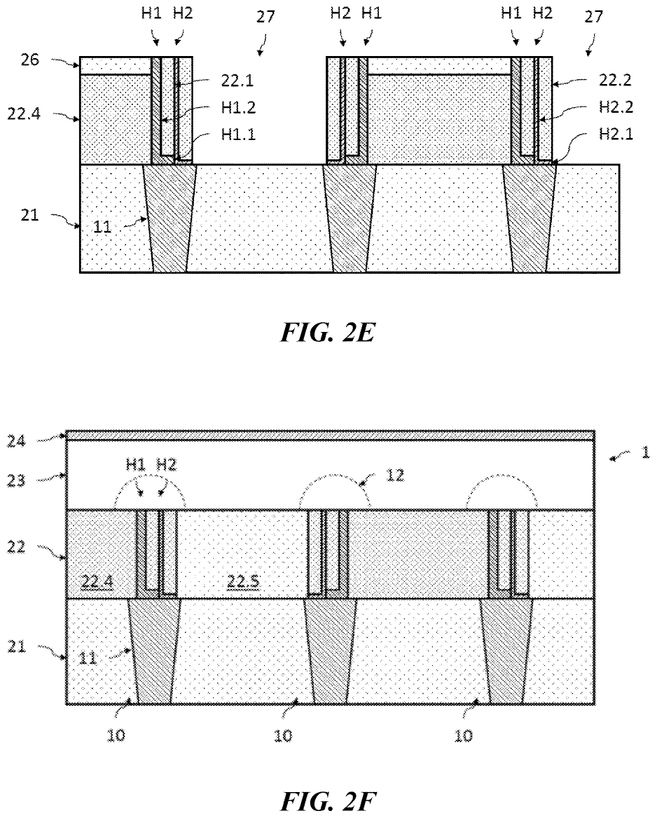

FIGS. 2A to 2F illustrate different steps of a method for manufacturing an integrated circuit 1 including a memory cell 10 according to one embodiment, and here a matrix of identical memory cells.

With reference to FIG. 2A, the lower insulating layer 21, for example of SiO₂, is made on a FEOL structure (not represented). This FEOL (Front End Of Line) structure contains electronic elements such as field effect transistors.

Lower conductive contacts 11 vertically cross the lower insulating layer 21. They are made of an electrically conductive material, for example one or more metals such as tungsten.

A first insulating layer 25, made for example of a silicon nitride, is deposited so as to cover the lower insulating layer 21 and the conductive contacts 11. Its thickness substantially corresponds to the height of the resistive elements. A second insulating layer 26, made for example of a silicon oxide, is deposited onto the first insulating layer 25.

With reference to FIG. 2B, through openings 27 are made through the second insulating layer 26 and then the first insulating layer 25, to open out onto the lower insulating layer 21 and free up an upper surface of each conductive contact 11.

A first thin conductive layer 28 is then conformally deposited, to continuously cover the upper face of the second insulating layer 26, the flanks of the second insulating layer 26 and of the first insulating layer 25, and the free surface of the conductive contacts 11 and of the lower insulating layer 21. This first thin conductive layer 28 is to form the first resistive elements H1. In this example, it is made of TiSiN deposited by CVD. The thickness on the flanks corresponds to the thickness e1 of what will be the resistive elements H1.

A first thin passivation layer 29 is then conformally deposited to continuously cover the first thin conductive layer 28. This layer is to form the first spacers 22.1. Its thickness along the flanks will define the spacing in the plane XY between the resistive elements H1 and H2.

With reference to FIG. 2C, the first spacers 22.1 and the resistive elements H1 are made.

The thin passivation layer 29 is locally etched in the openings 27, as well as on the second insulating layer 26, so as to form the spacers 22.1 which extend vertically along the thin conductive layer 28 at the edges of the openings 27.

Subsequently, chemical wet etching or reactive plasma etching is performed, which removes the material from the thin conductive layer 28 not protected by the spacers 22.1. Reactive elements H1 in an L-shaped ‘wall’ architecture are therefore obtained. The lower parts H1.1 of the reactive elements H1 are in contact with the conductive contacts 11, and the vertical parts H1.2 extend vertically along the portions 22.4.

Thus, the upper face of the second insulating layer 26 is made free. From the thin conductive layer 28, the resistive elements H1 are obtained, each formed of a lower part H1.1 in contact with a conductive contact 11, and of a vertical part H1.2. From the thin passivation layer 29, only the portions 22.1 which cover the lower parts H1.1 and extend vertically along the vertical parts H1.2 are retained. These portions 22.1 form the first spacers.

With reference to FIG. 2D, steps similar to those of FIGS. 2B and 2C are reiterated for the purpose of making the second spacers 22.2 and the resistive elements H2.

For this, a second continuous thin conductive layer 30 is conformally deposited, so as to continuously cover the upper face of the second insulating layer 26, as well as the vertical flank of the spacer 22.1, and finally the free surface of the lower conductive contacts 11 and of the lower insulating layer 21. This second thin conductive layer 30 is to form the resistive elements H2. In this example, it is made of TiSiN deposited by ALD. The thickness on the flanks corresponds to the thickness e2 of what will be the resistive elements H2.

A second thin passivation layer 31 is conformally deposited to continuously cover the second thin conductive layer 30. This layer is to form the second spacers 22.2.

With reference to FIG. 2E, the second spacers 22.2 and the resistive elements H2 are made.

The passivation layer 31 is locally etched in the openings 27 as well as on the second insulating layer 26, so as to form the second spacers 22.2 which extend vertically along the thin conductive layer 30 at the edges of the openings 27.

Subsequently, chemical wet etching or reactive plasma etching is performed, which removes the material from the thin conductive layer 30 not protected by the spacers 22.2. Reactive elements H2 in an L-shaped ‘wall’ architecture are therefore obtained. The lower parts H2.1 of the reactive elements H2 are in contact with the conductive contacts 11, and the vertical parts H2.2 extend vertically along the spacers 22.1.

Thus, the upper face of the second insulating layer 26 is again made free. From the second thin conductive layer 30, the resistive elements H2 are obtained, each formed of a lower part H2.1 in contact with a conductive contact 11, and of a vertical part H2.2 which extends vertically against the first spacer 22.1. From the second thin passivation layer 31, only the portions 22.2 which cover the lower parts H2.1 and extend vertically along the vertical parts H2.1 are retained. These portions 22.2 form the second spacers.

With reference to FIG. 2F, manufacturing of the memory cells 10 is completed. For this, a filling layer is deposited to fill the openings, followed by a chemical mechanical planarization to remove the excess filling material and thus obtain the portions 22.5, and to remove the second insulating layer 26 and reduce height of the resistive elements H1 and H2, as well as that of the spacers 22.1, 22.2. A planar continuous face is thus obtained.

Next, a layer 23 made of the phase change material is deposited so as to continuously cover the intermediate lower layer 22. Zones 12 are in electrical and thermal contact with the resistive elements H1, H2, which form the active portions of the memory cells. Finally, a conductive layer 24 is deposited so as to cover the phase change layer.

Thus, an integrated circuit 1 is obtained, including a matrix of identical memory cells, each memory cell 10 including at least two resistive elements H1, H2 connected in parallel, the electric resistances of which have the characteristics previously mentioned. Thus, memory cells are obtained, which have improved performance especially during the read operation of the SET state, and also during the RESET programming operation.

Embodiments have just been described. Various alternatives and modifications will appear to those skilled in the art.

In one embodiment, a memory cell (10) includes an active portion (12) of a phase change material having a crystallization temperature (T_{c}) and a melting temperature (T_{f}), is summarized as including: a first conductive contact (11); at least one first and one second resistive elements (H1, H2), electrically connected in parallel, and electrically coupled to the first conductive contact (11), the first resistive element (H1) having an electric resistance (R1) having: a first value (R1_{TREAD}) at a first temperature (T_{READ}) lower than the crystallization temperature (T_{c}), and a second value (R1_{TRESET}) at a second temperature (T_{RESET}) greater than the melting temperature (T_{f}), less than or equal to its first value (R1_{TREAD}), the second resistive element (H2) having an electric resistance (R2) having: a first value (R2_{TREAD}) at the first temperature (T_{READ}), greater than the first value (R1_{TREAD}) of the first resistive element (H1), and a second value (R2_{TRESET}) at the second temperature (T_{RESET}), lower than the second value (R1_{TRESET}) of the first resistive element (H1); the active portion (12), coupled to the first and second resistive elements (H1, H2); and a second conductive contact (24), coupled to the active portion (12).

The first and second resistive elements (H1, H2) each include a first part (H1.2, H2.2) extending from the first conductive contact (11) to the active portion (12), the first part (H1.2) of the first resistive element (H1) being spaced from the first part (H2.2) of the second resistive element (H2) by a first spacer (22.1) made of an electrically insulating material.

The first and second resistive elements (H1, H2) each include a second part (H1.1, H2.1) extending from the first part (H1.2, H2.2) and located in contact with the first conductive contact (11), the first spacer (22.1) covering the second part (H1.1) of the first resistive element (H1).

The memory cell (10), including a second spacer (22.2) extending along a surface of the first part (H2.2) of the second resistive element (H2), opposite to the first spacer (22.1), and covering the second part (H2.1) of the second resistive element (H2).

The first and second resistive elements (H1, H2) have identical or different thicknesses.

At the first temperature (T_{READ}), the first value (R2_{TREAD}) of the electric resistance (R2) of the second resistive element (H2) is at least 2 times greater than the first value (R1_{TREAD}) of the electric resistance (R1) of the first resistive element (H1).

The first resistive element (H1) and/or the second resistive element (H2) are made of materials based on a titanium silicon and/or tungsten nitride.

The active portion (12) is made of a chalcogenide, preferably a ternary chalcogenide compound.

In one embodiment, integrated circuit (1), includes a matrix of identical memory cells (10).

A method for manufacturing at least one memory cell (10) according to any one of claims 1 to 8, is summarized as including the following steps: making a first insulating layer (21) and at least one first conductive contact (11) passing therethrough to open out onto an upper face; making a second insulating layer (25) covering the first insulating layer (21) and the first conductive contact (11); making at least one opening (27) through the second insulating layer (25) and opening out onto the first conductive contact (11); depositing a first thin conductive layer (28) onto a flank of the opening (27), and local etching to obtain the first resistive element (H1); depositing a thin insulating layer (29) onto a flank of the first resistive element (H1), and local etching to obtain a first spacer (22.1); depositing a second thin conductive layer (30) onto a flank of the first spacer (22.1), and local etching to obtain the second resistive element (H2); making the active portion (12); and making the second conductive contact (24).

The first thin conductive layer (28) is deposited by chemical vapor deposition.

The second thin conductive layer (30) is deposited by atomic layer deposition.

The first thin conductive layer (28) and/or the second thin conductive layer (30) are made of a material based on a titanium silicon and/or tungsten nitride.

The manufacturing method, including, before the step of making the active portion (12), a step of filling the opening (27), followed by a step of making a continuous layer (23) of the phase change material.

A method for manufacturing an integrated circuit (1) is summarized as including a matrix of identical memory cells (10) simultaneously made by the method.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A memory cell, comprising an active portion of a phase change material having a crystallization temperature and a melting temperature, including:
a first conductive contact;
at least one first and one second resistive elements, electrically connected in parallel, and electrically coupled to the first conductive contact,
the first resistive element having an electric resistance having:
a first value at a first temperature lower than the crystallization temperature, and
a second value at a second temperature greater than the melting temperature, less than or equal to its first value,
the second resistive element having an electric resistance having:
a first value at the first temperature, greater than the first value of the first resistive element, and
a second value at the second temperature, lower than the second value of the first resistive element;
the active portion, coupled to the first and second resistive elements; and
a second conductive contact, coupled to the active portion.

2. The memory cell according to claim 1, wherein the first and second resistive elements each include a first part extending from the first conductive contact to the active portion, the first part of the first resistive element being spaced from the first part of the second resistive element by a first spacer made of an electrically insulating material.

3. The memory cell according to claim 2, wherein the first and second resistive elements each include a second part extending from the first part and located in contact with the first conductive contact, the first spacer covering the second part of the first resistive element.

4. The memory cell according to claim 3, further comprising a second spacer extending along a surface of the first part of the second resistive element, opposite to the first spacer, and covering the second part of the second resistive element.

5. The memory cell according to claim 1, wherein the first and second resistive elements have identical or different thicknesses.

6. The memory cell according to claim 1, wherein, at the first temperature, the first value of the electric resistance of the second resistive element is at least 2 times greater than the first value of the electric resistance of the first resistive element.

7. The memory cell according to claim 1, wherein the first resistive element and/or the second resistive element are made of materials based on a titanium silicon and/or tungsten nitride.

8. The memory cell according to claim 1, wherein the active portion is made of a chalcogenide, preferably a ternary chalcogenide compound.

9. A method for manufacturing at least one memory cell, the method comprising:
making a first insulating layer and at least one first conductive contact passing therethrough to open out onto an upper face;
making a second insulating layer covering the first insulating layer and the first conductive contact;
making at least one opening through the second insulating layer and opening out onto the first conductive contact;
depositing a first thin conductive layer onto a flank of the opening, and local etching to obtain the first resistive element;
depositing a thin insulating layer onto a flank of the first resistive element, and local etching to obtain a first spacer;
depositing a second thin conductive layer onto a flank of the first spacer, and local etching to obtain the second resistive element;
making an active portion of a phase change material having a crystallization temperature and a melting temperature, the active portion being coupled to the first and second resistive elements; and
making second conductive contact coupled to the active portion.

10. The manufacturing method according to claim 9, wherein the first thin conductive layer is deposited by chemical vapor deposition.

11. The manufacturing method according to claim 9, wherein the second thin conductive layer is deposited by atomic layer deposition.

12. The manufacturing method according to claim 9, wherein the first thin conductive layer and/or the second thin conductive layer are made of a material based on a titanium silicon and/or tungsten nitride.

13. The manufacturing method according to claim 9, further comprising, before the step of making the active portion, a step of filling the opening, followed by a step of making a continuous layer of the phase change material.

14. A method, comprising:
depositing a first insulating layer on a first conductive contact of a memory cell;
exposing the first conductive contact by forming a trench in the insulating layer;
depositing a first resistive element of the memory cell in the trench on a top surface of the first conductive contact;
depositing a second resistive element of the memory cell in the trench on the top surface of the first conductive contact adjacent to the first resistive element;
filling the trench with a first insulating material;
depositing a layer of phase change material of the memory cell on a top surface of the resistive element, on a top surface of the second resistive element, and on a top surface of the first insulating material; and
depositing a second conductive contact on the layer of phase change material.

15. The method of claim 14, wherein the first and second resistive elements each have an L shape.

16. The method of claim 15, wherein a lower portion of the first resistive element is in contact with a lower portion of the second resistive element.

17. The method of claim 16, further comprising:
exposing a portion of the top surface of the first conductive contact by patterning the first resistive element; and
depositing the second resistive element on the portion of the top surface of the first conductive contact after patterning the first resistive element.

18. The method of 15, wherein a second insulating material is positioned between an upper portion of the first resistive element and an upper portion of the second resistive element.

19. The method of claim 18, wherein the second conductive contact is on a top surface of the second insulating material.

20. The method of claim 14, wherein the layer of phase change material is positioned on first and second resistive elements of a plurality of memory cells.
